(19) United States
(12) Patent Application Publication
(10) Pub. No.: US 2010/0187093 A1
(43) Pub. Date: Jul. 29, 2010

(54) SPUTTERING TARGET, METHOD OF MANUFACTURING THIN FILM, AND DISPLAY DEVICE

(75) Inventor: Masaki Kuribayashi, Kawasaki-shi (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/677,584

(22) PCT Filed: May 20, 2009
(86) PCT No.: PCT/JP2009/059242

§ 371 Date: Apr. 7, 2010

(30) Foreign Application Priority Data
May 22, 2008 (JP) 2008-133796

(51) Int. Cl. C23C 14/34

(52) U.S. Cl. 204/192.1

(57) ABSTRACT

In forming an LaB₆ thin film by magnetron sputtering, monocrystallinity in a large-area domain direction of the obtained LaB₆ thin film is improved. A sputtering target containing boron (B), lanthanum (La) and carbon (C) atoms is used.

### TECHNICAL FIELD

The present invention relates to a target which is formed of a sintered body of a lanthanum boride compound containing a minute amount of carbon atoms, a method of manufacturing a crystalline thin film, an electron source, and a display device.

### BACKGROUND ART

As described in Patent References 1, 2 and 3, a thin film of a lanthanum boride compound such as LaB₆ is known as a secondary electron generation film. It is also known to form a crystalline thin film of a lanthanum boride compound by a sputtering method as described in Patent References 1, 2 and 3. It is also known to use a sintered body of a lanthanum boride compound such as LaB₆ as a target used in the above-described sputtering method as described in Patent Reference 4.

### BACKGROUND ART

### Patent References

### Patent Reference 1:

Japanese Patent Laid-open Publication No. 01-286228

### Patent Reference 2:

Japanese Patent Laid-open Publication No. 03-232959

### Patent Reference 3:

Japanese Patent Laid-open Publication No. 03-101033

### Patent Reference 4:

Japanese Patent Laid-open Publication No. 06-248446

### DISCLOSURE OF INVENTION

### Problems to be Solved by the Invention

But, when the thin film of a lanthanum boride compound formed by a sputtering apparatus and a sputtering method using a conventional target is applied to a secondary electron source film, the electron generation efficiency of the secondary electron source film is not satisfactory.

Especially, in a case where the thin film of the lanthanum boride compound such as LaB₆ is used for FED (Field Emission Display) or SED (Surface-Conduction Electron-emitter Display), the display device is not provided with satisfactory brightness.

According to the study made by the inventors of the present invention, the above problem arises from a point that crystal growth of the thin film formed of the lanthanum boride compound is insufficient. Especially, if the thin film has a very small thickness of 10 nm or below, monocrystallinity is not sufficient in a large-area domain direction, and a large-area domain is not formed due to crystal grain boundaries.

According to the study made by the inventors of the present invention, it was found that secondary electron generation efficiency can be improved substantially by improving monocrystallinity in a large-area domain direction, and especially an electron generation device such as FED or SED can produce improvement of brightness. The improvement of brightness leads to lowering of an anode voltage of the FED or the SED and also leads to expansion of a usable range of a usable phosphor or its selection range.

The present invention aims to provide a production apparatus capable of improving monocrystallinity in a large-area domain direction when the thin film of the lanthanum boride compound such as LaB₆ is formed, and a method of manufacturing the thin film.

The invention also aims to provide an electron source display device which produces improved brightness.

### Means for Solving the Problem

First, the present invention provides a sputtering target which is a sintered body (herein after called as “B—La—C sintered body”) containing boron (B), lanthanum (La) and carbon (C) atoms.

Second, the present invention provides a method of manufacturing a thin film, comprising forming a crystalline thin film containing boron (B), lanthanum (La) and carbon (C) atoms by a sputtering method using a sputtering target containing boron (B), lanthanum (La) and carbon (C) atoms.

Third, the present invention provides a method of manufacturing a thin film, comprising forming a crystalline thin film containing boron (B), lanthanum (La) and carbon (C) atoms by a sputtering method using a sputtering target containing boron (B) and lanthanum (La) atoms in the presence of a carbon source gas.

Fourth, the present invention relates to an electron source having a crystalline thin film containing boron (B), lanthanum (La) and carbon (C) atoms.

Fifth, the present invention provides a display device provided with an electron source having a crystalline thin film containing boron (B), lanthanum (La) and carbon (C) atoms.

### EFFECT OF THE INVENTION

According to the present invention, the carbon atom can be contained in the crystalline thin film of a lanthanum boride compound such as LaB₆, and secondary electron generation efficiency by the crystalline thin film can be improved. According to the invention, brightness of the FED or SED display device is also improved.

### BRIEF DESCRIPTION OF THE DRAWINGS

FIG. 1 is a schematic view showing a first example of a magnetron sputtering apparatus used for a method of manufacturing a thin film according to the invention.

FIG. 2 is a schematic sectional view of an electron generation device according to the invention.

FIG. 3 is enlarged sectional views of LaB₆ thin films containing a minute amount of carbon, (a) is an LaB₆ thin film containing a minute amount of carbon according to the invention, and (b) is an LaB₆ thin film not according to the present invention.

FIG. 4 is a schematic view showing a second example of the magnetron sputtering apparatus used for the method of manufacturing a thin film according to the present invention.

FIG. 5 is a schematic view showing a third example of the magnetron sputtering apparatus used for the method of manufacturing a thin film according to the present invention.

### MODE FOR CARRYING OUT THE INVENTION

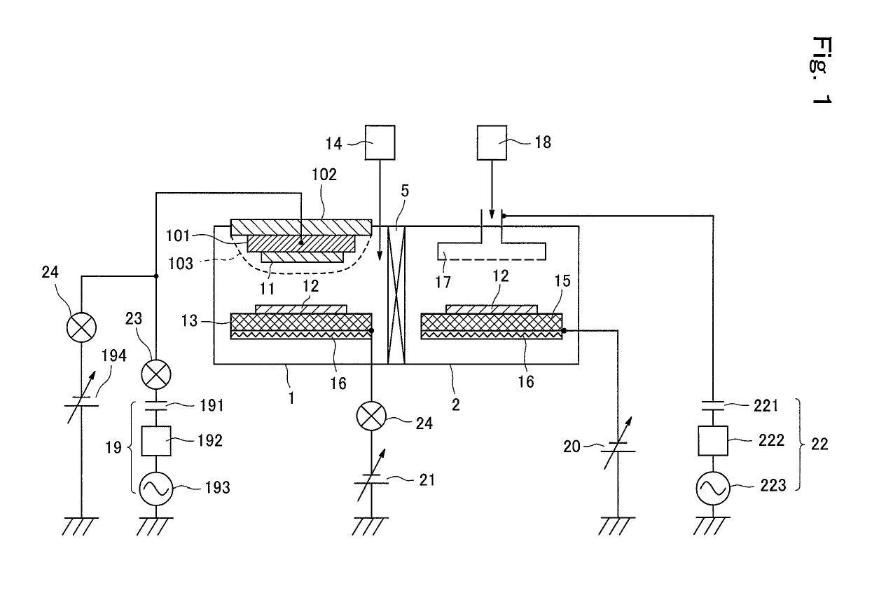

FIG. 1 is a schematic view showing a first example of a magnetron sputtering apparatus used for a method of manufacturing a thin film according to the present invention. Reference numeral 1 is a first vessel, 2 is a second vessel (annealing unit) vacuum-connected to the first vessel 1, 3 is a substrate charging chamber, 4 is a discharging chamber, 5 is a gate valve, 11 is a sputtering target, 12 is a substrate, 13 is a substrate holder (first substrate holder) for holding the substrate 12, 14 is a sputtering gas feed system, 15 is a substrate holder (second substrate holder), 16 is a heating mechanism, 17 is a plasma electrode, 18 is a gas feed system for a plasma source, 19 is a sputtering high-frequency power source system, 101 is a cathode to which the target 11 can be attached, 102 is a magnetic field generation device, 103 is a magnetic field region, 191 is a blocking capacitor, 192 is a matching circuit, 193 is a high-frequency power source, 194 is a sputtering bias power source, 20 is an (annealing) substrate bias power source (third DC power source), 21 is a substrate bias power source (second DC power source), 22 is a high-frequency power source system for a plasma source, 221 is a blocking capacitor, 222 is a matching circuit, 223 is a high-frequency power source, and 23 is a low-frequency cut filter (filter) which filters out a low-frequency component from the high-frequency power source 193 to provide high-frequency component power. Reference numeral 24 is a high-frequency cut filter which filters out a high-frequency component (e.g., a high-frequency component of 1 KHz or more, especially, 1 MHz) contained in DC power from the DC power sources 21 and 194.

According to the invention, there is used a target 11 containing boron (B), lanthanum (La) and carbon (C) atoms or a target 11 containing boron (B) and lanthanum (La) atoms. The former is called as the B—La—C target 11, the latter is called as the B—La target 11, and they are simply called as the target 11 collectively.

For the B—La—C target 11, a B—La—C sintered body can be used. A method of manufacturing the B—La—C sintered body is described later. For the B—La target 11, a sintered body (B—La sintered body) containing boron (B) and lanthanum (La) atoms can be used. For example, the B—La sintered body can be manufactured as an LaB₆ sintered body by a known method.

The substrate 12 is placed on the holder 13 in the first vessel 1 to face the substrate 12 to the cathode 101, and the vessel interior is vacuum exhausted and heated (increasing up to a temperature for sputtering performed later). Heating is performed by the heating mechanism 16. Then, a plasma source gas (helium gas, argon gas, Krypton gas, xenon gas) is introduced from the sputtering gas feed system 14 to set a prescribed pressure (0.01 Pa to 50 Pa, preferably, 0.1 Pa to 10 Pa), and the sputtering power source 19 is used to start forming a film.

Subsequently, high-frequency power (frequency of 0.1 MHz to 10 GHz, preferably 1 MHz to 5 GHz, and applied power of 100 watts to 3000 watts, preferably 200 watts to 2000 watts) is applied from the high-frequency power source 193 to generate plasma, and DC power (voltage) is set by the first DC power source 194 to a prescribed voltage (−50 volts to −1000 volts, preferably −10 volts to −500 volts), and sputtering film formation is performed. On the substrate 12 side, the DC power (voltage) is applied to the substrate holder 13 at a prescribed voltage (0 volt to −500 volts, preferably −10 volts to −100 volts) by the second DC power source 21. DC power (first DC power) from the first DC power source 194 may be applied before the application of the high-frequency power from the high-frequency power source 193, but it may be applied simultaneously when the high-frequency power is applied, and it may also be applied continuously even after the application of the high-frequency power is completed.

Positions where the DC power and/or the high-frequency power from the second DC power source 21 and/or the sputtering high-frequency power source 19 is applied to the cathode 101 are preferably plural points symmetrically to the center point of the cathode 101. For example, the symmetric positions to the center point of the cathode 101 can be determined to be the plural application positions of the DC power and/or the high-frequency power.

The magnetic field generation device 102 made of a permanent magnet or an electromagnet is arranged to position behind the cathode 101, so that the surface of the target 11 can be exposed to the magnetic field 103. It is desirable that the magnetic field 103 does not reach the surface of the substrate 12, but the magnetic field 103 may reach the surface of the substrate 12 if its level does not narrow the large-area monocrystalline domain of the boron-lanthanum compound film containing a minute amount of carbon.

The high-frequency cut filter 24 which is disposed on the side of the first DC power source 194 used in the invention can provide another effect of protecting the first DC power source 194.

S and N poles of the magnetic field generation means 102 can be arranged to have a mutually reverse polarity in a perpendicular direction with respect to the plane surface of the cathode 103. It is determined that the mutually adjacent magnets have a mutually reverse polarity in a horizontal direction with respect to the plane surface of the cathode 103. And, the S and N poles of the magnetic field generation means 102 can also be arranged to have a mutually reverse polarity in a horizontal direction with respect to the plane surface of the cathode 103. In this case, the mutually adjacent magnets are also determined to have a mutually reverse polarity in a horizontal direction with respect to the plane surface of the cathode 103.

In a preferable embodiment of the present invention, the magnetic field generation means 102 can perform an oscillating movement in a horizontal direction with respect to the surfaces of the cathode 101 or the target 11.

The filter 23 used in the present invention can filter out the low-frequency component (frequency component of 0.01 MHz or less, particularly 0.001 MHz or less) from the high-frequency power source 193.

Besides, the present invention can increase the average area of the monocrystalline domain by application of the DC power (voltage) from the second DC power source 21 on the substrate 12 side to the substrate holder 13. This second DC power (voltage) may be pulse waveform power having a DC component (DC component to the ground) in time average.

The present invention can also increase the average area of the monocrystalline domain by adding an annealing process.

After the film is formed by the magnetron sputtering method described above, the substrate 12 is conveyed into the second vessel 2 via the gate valve 5 while keeping the vacuum state and placed on the holder 15 in the second vessel 2. And annealing (200 degrees C. to 800 degrees C., preferably 300 degrees C. to 500 degrees C.) is started by the heating mechanism 16. When annealing is performed, a plasma source gas (hydrogen gas, argon gas, krypton gas, xenon gas, hydrogen gas, nitrogen gas or the like) plasma is irradiated to the substrate 12 by the gas feed system 18 for the plasma source, and a prescribed voltage (−10 volts to −1000 volts, preferably −100 volts to −500 volts) may be applied by the third DC power source 20. After the annealing is completed, the second vessel 2 interior is returned to the atmospheric pressure, and the substrate 12 is removed.

Besides, the power source system 22 for the plasma source is provided with the blocking capacitor 221, the matching circuit 222 and the high-frequency power source 223 and can apply high-frequency power (frequency of 0.1 MHz to 10 GHz, preferably 1 MHz to 5 GHz, and applied power of 100 watts to 3000 watts, preferably 200 watts to 2000 watts) from the high-frequency power source 223.

The substrate holder 15 is heated to have a prescribed temperature by the heating mechanism 16, and the substrate 12 placed on the substrate holder 15 is undergone the annealing treatment. Here, a preset temperature and an annealing treatment time of the heating mechanism 16 are adjusted to optimum values depending on the required film properties. At this time, an annealing effect can be enhanced furthermore by irradiating a particle beam of ions, electrons, radicals (active species) or the like by the substrate 12. The irradiation of the particle beam of ions, electrons, radicals (active species) or the like can be performed during, after or before heating the substrate 12.

In this example, an example of the plasma source using a parallel plate type high-frequency discharge electrode 17 (plasma electrode 17) is described, but a bucket type ion source, an ECR (electron cyclotron) ion source, an electron beam irradiation device or the like can also be used. At this time, the substrate holder 15 on which the substrate 12 is placed may have a floating electrical potential, but it is also effective to apply a prescribed bias voltage from the third DC power source 21 in order to have the energy of the incident particles at a prescribed level.

The substrate 12 having undergone the annealing treatment is removed into the atmosphere through an unshown conveying chamber, conveying mechanism, and charging and discharging chambers. After forming the thin film of a lanthanum boride compound such as LaB₆ containing a minute amount of carbon, this apparatus performs the annealing treatment and others without removing the substrate 12 into the atmosphere. Therefore, the thin film surface is not contaminated by the components in the atmosphere, and the thin film of the lanthanum boride compound having a good crystal structure can be obtained.

The B—La—C sintered body used as the B—La—C target 11 of the invention can be produced by the following method.

For example, material powder of lanthanum boride (LaB₆) is pulverized by a pulverizer or a ball mill for a prescribed time to produce powder having an average grain diameter of 0.1 to 100 μm. Besides, carbon powder such as activated carbon and the above-described lanthanum boride (LaB₆) powder are mixed by a ball mill such that a weight ratio of carbon to a total weight becomes 0.0001 to 0.1, and the lanthanum boride (LaB₆) powder containing carbon can be obtained. For the carbon powder, carbide powder such as silicon carbide (SiC) powder can also be used.

Subsequently, a sintered body can be obtained by molding and firing the above-described carbon-containing lanthanum boride (LaB₆) powder by a hot press machine. Conditions for the hot press machine are as follows.

Pressure: 10 kg/cm² to 500 kg/cm², preferably 100 kg/cm² to 300 kg/cm²
Temperature: 1000 degrees C. to 3000 degrees C., preferably, 1500 degrees C. to 2500 degrees C.
Duration: 0.5 hour to 5 hours, preferably 1 hour to 3 hours

The same sintered body can also be obtained by pressing and shaping by a cold isostatic press, and then sintering by hot isostatic pressing.

After the above-described sintered body is machined into a prescribed shape, it is bonded to a copper plate by bonding, and a finishing process is performed to obtain a product (La—B—C target 11).

In a case where the B-LA target 11 is used, a hydrocarbon gas such as methane, ethane, propane, ethylene or acetylene is mixed with the plasma source gas as the carbon source gas, the mixture is introduced into the sputtering chamber, and a lanthanum boride crystalline thin film containing a minute amount of carbon atom can be obtained by a sputtering method in the presence of the carbon source gas. It is preferable that a flow rate of the carbon source gas is set to 1/10 to 1/10000 of the flow rate of the plasma source gas.

The thin film of the lanthanum boride compound containing a minute amount of carbon used in the invention can also contain another component such as Ba metal.

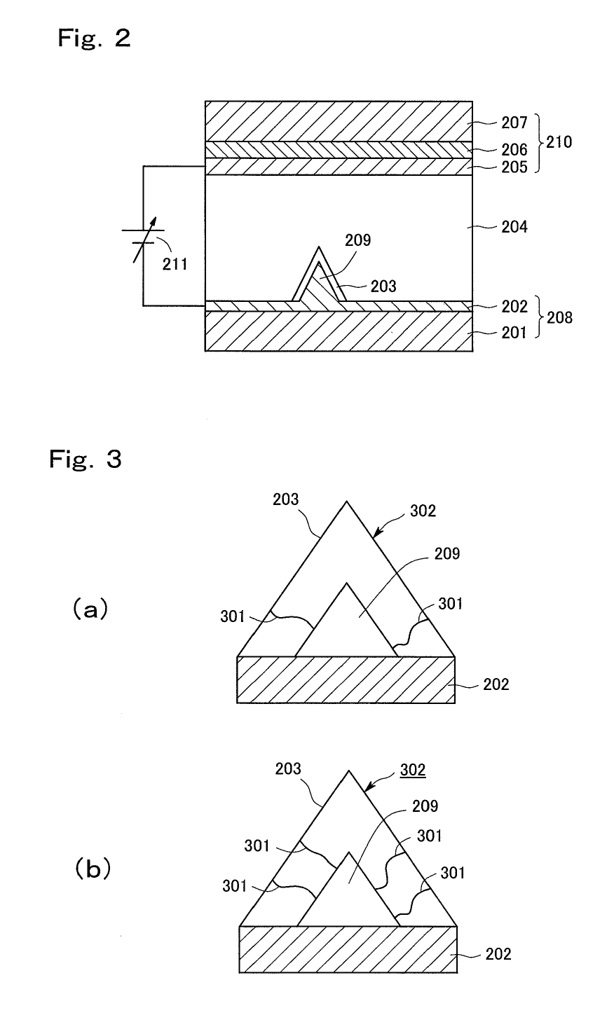

In FIG. 2, 208 is an electron source substrate which has thereon a molybdenum film (cathode electrode) 202 having a cone shaped projection 209 and an LaB₆ film 203 covering the projection 209 of the molybdenum film. Reference numeral 210 is a phosphor substrate which is comprised of a glass substrate 207, a phosphor film 206 formed on it, and an anode electrode 204 made of a thin aluminum film. A space 204 between the electron source substrate 208 and the phosphor substrate 210 is a vacuum space. A DC voltage of 100 volts to 3000 volts is applied to between the cathode electrode 202 and an anode electrode 205 to emit an electron beam from the tip end of the projection 209 of the molybdenum film 202 covered with the LaB₆ film 203 containing a minute amount of carbon toward the anode electrode 205. And, the electron beam is transmitted through the anode electrode 205 to hit the phosphor film, thereby enabling to produce fluorescence.

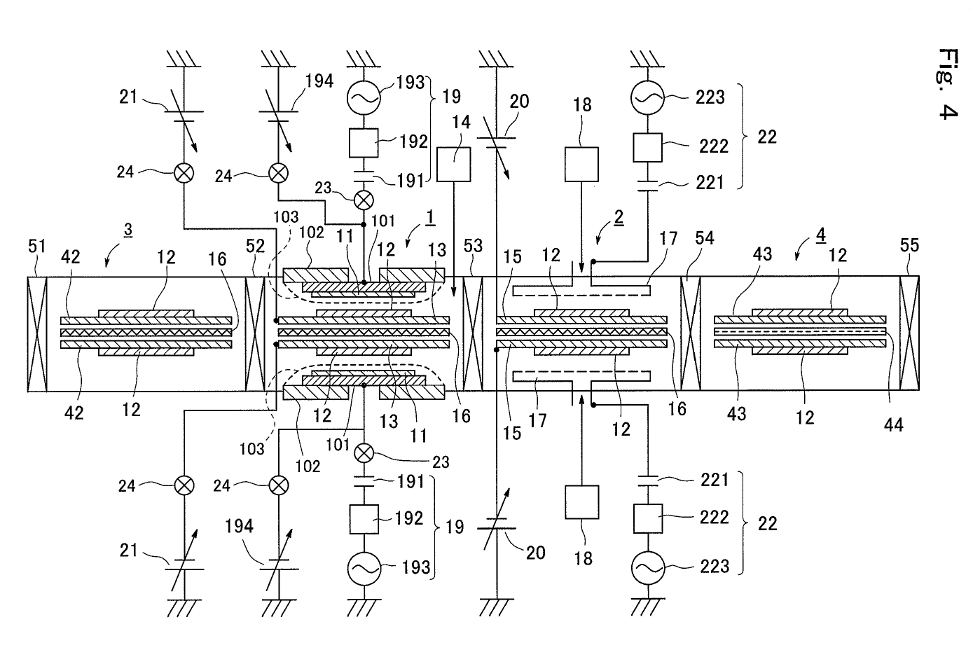

FIG. 3 is enlarged sectional views of the projection 209 covered with the LaB₆ film 203 containing a minute amount of carbon of FIG. 2. The projection 209 of FIG. 3(a) is covered with the LaB₆ film 203 containing a minute amount of carbon formed according to the present invention, and a monocrystalline large-area domain 302 which is surrounded by crystal grain boundaries 301 is formed in the film. The monocrystalline large-area domain 302 has an average area in a range of 1 μm² to 1 mm², and preferably 5 μm² to 500 μm².

The projection 209 of FIG. 3(b) is covered with an LaB₆ 303 which is formed without containing a minute amount of carbon, and the monocrystalline large-area domain 302 is also formed.

It was found that the LaB₆ film 203 containing a minute amount of carbon according to the invention was improved as illustrated in view of the area of the large-area domain 302 in comparison with the monocrystalline domain of the LaB₆ film 303 formed without containing a minute amount of carbon not according to the present invention.

When used as the electron source substrate of FIG. 2, the LaB₆ film 203 containing a minute amount of carbon according to the invention had high brightness in comparison with the LaB₆ film 303 formed without containing a minute amount of carbon not according to the present invention.

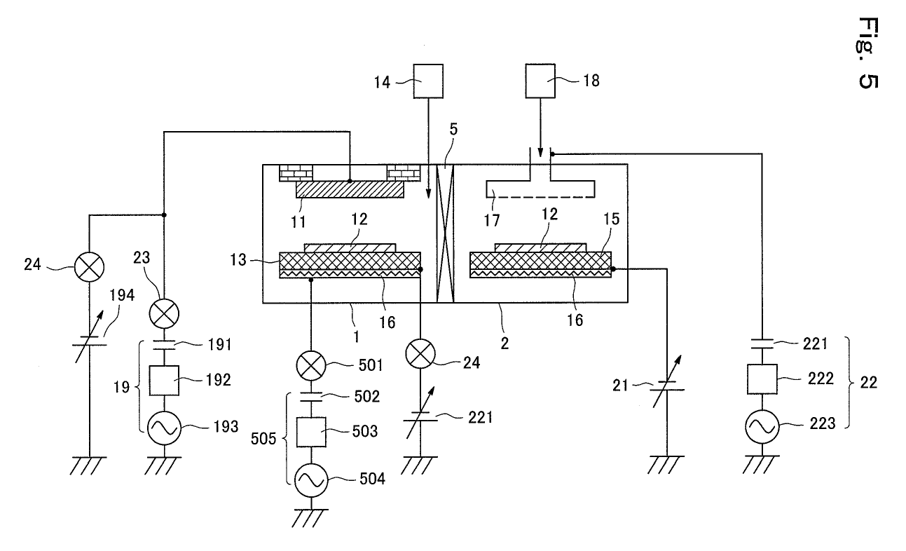

The apparatus shown in FIG. 4 is a schematic view showing a second example of a magnetron sputtering apparatus used for a method of manufacturing a thin film according to the invention. The example of FIG. 4 is an example of a vertical in-line sputtering apparatus and a sectional view of the apparatus viewed from above. Like reference numerals as those of FIG. 1 denote like parts or corresponding parts.

Two substrates 12 are fixed to two substrate holders 42, respectively, conveyed together with the substrate holders 42 from the atmosphere side to the charging chamber 3 through a gate valve 51 and then treated.

When a tray (not shown) is conveyed into the charging chamber 3, the gate valve 51 is closed, and the chamber interior is evacuated by an unshown exhaust system. When evacuated to a prescribed pressure or below, a gate valve 52 to the first vessel 1 is opened, the tray is conveyed into the first vessel 1, and the gate valve 52 is closed. Then, the LaB₆ thin film containing a minute amount of carbon is formed in the same manner as described in the first example, and the sputtering gas is exhausted in the same manner as in the first example. After the exhaustion to the prescribed pressure, a gate valve 53 to the second vessel 2 is opened, and the tray is conveyed to the second vessel 2. The heating mechanism 16 kept at a prescribed temperature is arranged within the second vessel 2, and the substrate 12 can be undergone the annealing treatment together with the substrate holder 15. At this time, electrons, ions, radicals or the like may be used similar to the example shown in FIG. 1. After completing the annealing, the vessel interior is evacuated, a gate valve 54 to the discharging chamber 4 is opened, the tray is conveyed to the discharging chamber 4, and the substrate 12 is fixed to a substrate holder 43. Then, the gate valve 54 is closed. The discharging chamber 4 is provided with a cooling panel 44 for lowering the substrate temperature after the annealing. After lowering to a prescribed temperature, the discharging chamber 4 interior is returned to the atmospheric pressure by a leak gas (helium gas, nitrogen gas, hydrogen gas, argon gas or the like), and a gate valve 55 is opened to remove the tray into the atmosphere side.

In the above example, the tray was treated in a stationary state in the first vessel 1 and the second vessel 2 but may be treated while moving. In such a case, the first vessel 1 and the second vessel 2 may be added as required in order to balance with speed up of the treating speed of the apparatus as a whole.

Here, as the magnetron sputtering method, the method using both the high-frequency power and the DC power at the same time was described above. But, magnetron sputtering may be performed by the first DC power source 194 without application of a high frequency depending on the film quality required. This case has an advantage that the high-frequency power source 193 and the matching circuit 192 are unnecessary, and the apparatus cost can be reduced.

FIG. 5 is a schematic view showing a third example of the magnetron sputtering apparatus used for a method of manufacturing a thin film according to the invention. The apparatus of this example has a high-frequency power source system 505 for a substrate added to the apparatus of FIG. 1. The high-frequency power source system 505 for a substrate is used to apply high-frequency power to the substrate 12 through the substrate holder 13.

The sputtering high-frequency power source system 19 in this example is provided with the blocking capacitor 191, the matching circuit 192 and the high-frequency power source (first high-frequency power source) 193 in the same manner as the apparatus of FIG. 1. And, the sputtering high-frequency power source system 19 is connected to the filter (first filter) 23 which filters out the low-frequency component from the high-frequency power source 193.

The high-frequency power source system 505 for a substrate added in this example is provided with a blocking capacitor 502, a matching circuit 503 and a high-frequency power source (second high-frequency power source) 504. And, the high-frequency power source system 505 for a substrate is connected to a filter (second filter) 501 which filters out a low-frequency component from the high-frequency power source 504.

The high-frequency power source system 505 for a substrate outputs high-frequency power (frequency of 0.1 MHz to 10 GHz, preferably 1 MHz to 5 GHz, and applied power of 100 watts to 3000 watts, preferably 200 watts to 2000 watts) from the high-frequency power source 504 and can apply the high-frequency power to the substrate 12 through the filter 501 which filters out a low-frequency component from the blocking capacitor 502, the matching circuit 503 and the high-frequency power source 504. The use of the filter 501 may be omitted.

The electron generating device produced by the apparatus shown in FIG. 5 could achieve brightness far brighter than the phosphor brightness achieved by the example 1.

According to the present invention, the magnet unit used for magnetron sputtering can be a generally used permanent magnet.

In a case where the magnetron sputtering is performed after the tray is stopped from moving, a target having an area slightly larger than the substrate 12 is provided, and a plurality of magnet units are arranged on the back surface of the target with an appropriate space among them and caused to make translational movement in a direction parallel to the surface of the target. Thus, a good film thickness uniformity and a high utilization coefficient of the target can be obtained. In a case where the sputtering is performed while moving the tray, a magnet unit and a target having a width smaller than the length of the substrate can be used with respect to the moving direction of the substrate.

The preferable embodiments and examples of the present application have been described with reference to the accompanying drawings, but the present invention is not limited to the embodiments and examples described above. It is to be understood that modifications and variations can be made without departing from the spirit and scope of the invention.

### EXPLANATION OF REFERENCE NUMERALS

1: First vessel
2: Second vessel
3: Substrate charging chamber
4: Discharging chamber
5, 51, 52, 53, 54, 55: Gate valve
11: Target
12: Substrate
13, 15, 42, 43: Substrate holder
14: Sputtering gas feed system
16: Heating mechanism
17: Plasma electrode
18: Gas feed system for plasma source
19: Sputtering high-frequency power source system
191, 221, 502: Blocking capacitor
192, 222, 503: Matching circuit
193, 223, 504: High-frequency power source
194: Sputtering DC power source (first DC bias power source)
20: (Annealing) substrate bias power source (third DC power source)
21: Substrate bias power source (second DC power source)
22: High-frequency power source system for plasma source
23, 501: Low-frequency cut filter which filters out a low-frequency component from the high-frequency power source 193
24: High-frequency cut filter
101: Cathode
102: Magnetic field generation device
103: Magnetic field region
201, 207: Glass substrate
202: Cathode electrode
203: LaB₆ thin film containing a minute amount of carbon
204: Vacuum space
205: Anode electrode
206: Phosphor film
208: Electron source substrate
209: Projection
210: Phosphor substrate
211: DC power source
301: Crystal grain boundary between monocrystals
302: Monocrystalline domain
303: LaB₆ thin film not according to the present invention
505: High-frequency power source system for substrate

1-2. (canceled)

3. A method of manufacturing a thin film, comprising:
forming a crystalline thin film containing boron (B), lanthanum (La) and carbon (C) atoms by a sputtering method using a sputtering target containing boron (B) and lanthanum (La) atoms in the presence of a carbon source gas.

4-5. (canceled)

6. A method of manufacturing an electron source, comprising:
forming a crystalline thin film containing boron (B), lanthanum (La) and carbon (C) atoms by a sputtering method using a sputtering target containing boron (B) and lanthanum (La) atoms in the presence of a carbon source gas.

7. A method of manufacturing a display device, comprising:
forming an electron source by a process of forming a crystalline thin film containing boron (B), lanthanum (La) and carbon (C) atoms by a sputtering method using a sputtering target containing boron (B) and lanthanum (La) atoms in the presence of a carbon source gas, and
manufacturing the display device by using the electron source.
